(19) United States
(12) Patent Application Publication
(10) Pub. No.: US 2014/0261672 A1
(43) Pub. Date: Sep. 18, 2014

(54) TITANIUM METAL AS ELECTRODE FOR ORGANIC SOLAR CELLS, FLEXIBLE ORGANIC SOLAR CELL ON TI FOIL AND METHOD OF MANUFACTURE

(71) Applicant: Miami University, Oxford, OH (US)

(72) Inventors: Lei L. Kerr, Oxford, OH (US); Huiying Jia, Oxford, OH (US)

(21) Appl. No.: 14/212,011

(22) Filed: Mar. 14, 2014

Related U.S. Application Data
(60) Provisional application No. 61/783,150, filed on Mar. 14, 2013.

(51) Int. Cl. H01L 51/44; H01L 51/00

(52) U.S. Cl. CPC H01L 51/441; H01L 51/0023
USPC 136/256; 438/82

(57) ABSTRACT

Titanium metal is used as an electrode in organic solar cells. Methods of making an organic photovoltaic cell are described using titanium foil that is etched using lower and higher concentrations of a hydrofluoric acid solution. Subsequently, other layers were disposed on the titanium foil to complete the solar cell. Etching at the lower concentration for about 30 seconds properly treated the surface of the electrode and resulted in an advantageous solar cell. Etching at the higher concentrations resulted in a poor morphology that resulted in poor performance.

### CROSS-REFERENCES TO RELATED APPLICATIONS

This application claims the benefit of U.S. Provisional Application No. 61/783,150 filed Mar. 14, 2013. This priority application is hereby incorporated by reference.

### STATEMENT REGARDING FEDERALLY-SPONSORED RESEARCH AND DEVELOPMENT

(Not Applicable)

### THE NAMES OF THE PARTIES TO A JOINT RESEARCH AGREEMENT

(Not Applicable)

### REFERENCE TO AN APPENDIX

(Not Applicable)

### BACKGROUND OF THE INVENTION

The invention relates generally to organic photovoltaic (PV) cells, and more specifically to an organic photovoltaic cell, a titanium electrode in an organic photovoltaic cell, and a method of making an organic photovoltaic cell on flexible titanium foil.

Solar energy conversion through solar cells includes absorbing light photons to generate excitons, dissociating and separating excitons, and transferring electrons to electrodes. Polymer (organic) solar cells typically include an anode, a donor and acceptor blended active layer, a hole collection layer, an electron collection layer, a cathode and a substrate. For polymer solar cells, the electrode is a major component because the electrode is used to extract separated charges from the photovoltaic region.

Currently, the most commonly used electrode material in polymer solar cells is tin-doped indium oxide (ITO). However, ITO is not an appropriate electrode technology for large-scale solar development because scarce resources of indium and high market demand for ITO have created large price fluctuations and future supply concerns. Furthermore, cost analyses suggest that ITO sputtering constitutes approximately half of the energy balance for processing lab-based polymer solar cells. In addition, ITO is not mechanically robust, thereby making it unsuitable for applications in flexible devices.

Flexible solar cells have several advantages over conventional glass or silicon (Si) wafer-based solar cell devices. Flexible solar cells fabricated on flexible polymer substrates or metal foil substrates are very lightweight, portable and mobile. Currently, installation and transportation costs constitute almost half of the installed cost of PV cells. Lightweight PV technology can reduce the costs of installed PV cells to make them comparable with today's electricity costs. Furthermore, compared with rigid glass substrates, flexible substrates enable roll-to-roll manufacturing, which is important to lower photovoltaic manufacturing costs.

The development of ITO-free electrodes is advantageous for the commercialization of organic solar cells. And despite the advantages of the prior art, there is a need for an inexpensive method of making organic photovoltaic cells, and in particular flexible substrate PV cells.

### BRIEF SUMMARY OF THE INVENTION

The invention contemplates a flexible organic solar cell that includes a titanium electrode, and a method of making the flexible organic solar cell.

Titanium metal in any configuration, which may be a thin foil, a thin film coating, a rod or any other configuration, is a surprisingly useful electrode in organic solar cells. However, not all morphologies of titanium will provide the same advantages as the more preferred morphologies prepared using an advantageous method described herein or its equivalent. Nevertheless, there is every reason to conclude that other methods may construct similarly, and possibly more, advantageous morphologies as described herein.

The structure of a new flexible solar cell constructed according to the invention preferably includes a titanium electrode, a donor/acceptor polymer layer (or layers) preferably mounted to the titanium electrode, a hole-conducting polymer layer (or layers) preferably mounted to the donor/acceptor polymer and another electrode mounted to the hole-conducting polymer layer.

For demonstrating the use of titanium as an electrode, a preferred flexible organic photovoltaic cell is described having a first layer of a properly treated titanium foil. A layer of donor/acceptor polymer, which may be P3HT:PCBM, is disposed on the first major surface of the titanium foil. A transparent, hole-conducting polymer layer, which may be PEDOT, is mounted to the donor/acceptor layer. A buffer layer, which may be PEDOT 4083, is mounted upon the opposite major surface of the P3HT:PCBM layer from the titanium foil, and a conducting layer or layers, which may be one, two or three relatively thin layers of PEDOT 1000, are disposed on the major surface of the PEDOT 4083 layer opposite the P3HT:PCBM layer. A thicker layer of PEDOT 1000 serves as a preferred blocking layer for P3HT:PCBM corrosion from a silver (Ag) paste (described below), but could be other materials. The blocking layer is disposed on the major surface of PEDOT 1000 opposite the PEDOT 4083. A silver (Ag) paste is disposed on the thicker layer of PEDOT 1000.

As shown in FIG. 1, the structure of the preferred inverted solar cell is Ti/P3HT:PCBM/PEDOT:PSS/Ag. Of course, a person having ordinary skill will understand how to modify the preferred PV cell from this description of a titanium electrode on which a layer of donor/acceptor polymer is disposed, on which a transparent, hole-conducting polymer layer is disposed, on which a buffer layer is disposed, on which a conducting layer is disposed, on which a blocking layer may be disposed and then on which a conductive paste layer is disposed.

It is contemplated that, given the right treatment, of which the following is but one example, any titanium layer can serve as an electrode in an organic PV cell. The titanium layer can be a titanium coating of virtually any useful thickness, a titanium foil, a titanium sheet, or a titanium rod, but virtually any other form of titanium can serve as an electrode. However, in order for a titanium foil to be a successful electrode, applicants found that the proper surface is important. The description below provides a simple surface treatment process to achieve a proper surface on a titanium foil. It is contemplated that other treatment processes exist that will result in a useful titanium electrode.

### BRIEF DESCRIPTION OF THE SEVERAL VIEWS OF THE DRAWINGS

FIG. 1 is a side view illustrating schematically the structure of an organic solar cell according to the present invention based on a titanium foil substrate.

FIG. 2 is a graph illustrating the current density relative to voltage (J-V) characteristics of an organic photovoltaic cell (OPV) made according to the present invention using a titanium foil substrate properly etched, and in this case proper etching resulted from using a 0.48 volume percent hydrofluoric (HF) acid solution.

FIG. 3a is a scanning electron microscope image at low magnification of a titanium foil surface properly etched.

FIG. 3b is a scanning electron microscope image at higher magnification than the image of FIG. 3a of a titanium foil surface properly etched.

FIG. 4 is a graph illustrating the J-V characteristics of an OPV made using a titanium foil substrate that was cleaned but not etched.

FIG. 5a is a scanning electron microscope image at low magnification of a titanium foil surface that has been cleaned but not etched.

FIG. 5b is a scanning electron microscope image at higher magnification than the image of FIG. 5a of a titanium foil surface that has been cleaned but not etched.

FIG. 6 is a graph illustrating the J-V characteristics of an OPV using a titanium foil substrate over-etched, and in this case over-etching resulted from using a 4.8 volume percent HF acid solution.

FIG. 7 is a table illustrating the comparative performance of different organic solar cells made using different substrates.

FIG. 8a is a scanning electron microscope image at lower magnification of a titanium foil surface over-etched.

FIG. 8b is a scanning electron microscope image at higher magnification than the image of FIG. 8a of a titanium foil over-etched.

In describing the preferred embodiment of the invention which is illustrated in the drawings, specific terminology will be resorted to for the sake of clarity. However, it is not intended that the invention be limited to the specific term so selected and it is to be understood that each specific term includes all technical equivalents which operate in a similar manner to accomplish a similar purpose. For example, the word connected or terms similar thereto are often used. They are not limited to direct connection, but include connection through other elements where such connection is recognized as being equivalent by those skilled in the art.

### DETAILED DESCRIPTION OF THE INVENTION

U.S. Provisional Application No. 61/783,150 filed Mar. 14, 2013 is incorporated in this application by reference.

The preferred flexible organic photovoltaic cell is illustrated schematically in FIG. 1 having a first layer of etched titanium (Ti) foil. Generally, this titanium substrate, exposed to air, will form a titania (TiO₂) layer on the outer surface thereof, which is the necessary semiconductive layer. A layer of P3HT:PCBM is disposed on the first major surface of the titanium foil adjacent the titania layer. This P3HT:PCBM layer serves as a bulk heterojunction electron acceptor and donor in the preferred embodiment.

A buffer layer of PEDOT 4083 is disposed upon the opposite major surface of the P3HT:PCBM layer from the titanium foil. At least one layer, and preferably three relatively thin layers, of PEDOT 1000 (serving as a conducting layer) is disposed on the major surface of the PEDOT 4083 layer opposite the P3HT:PCBM layer. A thicker layer of PEDOT 1000, which serves as a blocking layer to prevent the corrosion of P3HT:PCBM from penetration of the silver paste, is disposed on the major surface of the at least one layer of PEDOT 1000 opposite the PEDOT 4083. Finally, a silver (Ag) paste is disposed on the thicker layer of PEDOT 1000.

The layers of PEDOT 1000 and PEDOT 4083 are conductive polymers that serve as a transparent electrode to permit light to penetrate to the bulk heterojunction acceptor/donor layer (P3HT:PCBM). On the opposite surface of the cell, the titanium foil serves as an electrode, with the titania layer serving as a semiconductor. The cell shown and described herein is flexible, meaning it can be deformed significantly along its plane without damage. As an example, the PV cell according to the invention can be bent to a 5, 10, 30, 60 or 90 degree angle to its own plane without damage.

The manufacturing procedure for preparing the organic PV cells that are tested and described herein will be described. Titanium foils of about 250 μm thickness were cleaned by sonication in deionized (DI) water, ethanol, acetone and isopropyl alcohol for about 5 minutes each. The foils were then dried using compressed air.

Many of the cleaned foils were etched in a hydrofluoric acid (HF) solution, but some were not, and the non-etched foils are sometimes referred to hereafter as “clean” or “cleaned” because they were cleaned but not etched. Some of the remaining foils were etched with a first, higher concentration (for example, a 4.8 volume percent) of HF and others were etched with a second, lower concentration (for example, 0.48 volume percent) of HF. For both of the etching solution concentrations, the etching occurred for 30 seconds, followed by sonication in DI water for 5 minutes. Finally, all of the non-etched and etched foils were dried with compressed air.

Polythiophene (P3HT) was dissolved in cholorbenzene to make a 15 mg/ml solution. Pheynl-C₆₁-butyric acid methyl ester (PCBM) was dissolved in chlorobenzene to make a 12 mg/ml solution. Each of these solutions was stirred on a hot plate at about 50° C. for about one hour. The two solutions were mixed to form a P3HT:PCBM blend. The mixture was then further stirred for about 12 hours before filtering with a 0.45 μm PTFE filter.

As shown schematically in FIG. 1, the construction of the finished organic solar cell devices was the same regardless of whether or how the substrate foils had been etched. Each of the PV cells was constructed using the following procedure, with the only difference between cells being whether, and in what solution, the foils were etches prior to the following steps.

The P3HT:PCBM solution was spin coated on the foils at 800 rpm for one minute to create a layer as shown in FIG. 1. After spincoating, the foil was immediately transferred to a covered Petri dish for solvent vapor annealing for 1 hour. Next, the foil was annealed at 150° C. for 5 minutes. The substrates were treated with oxygen plasma at 30 W for 10 seconds to improve surface wettability.

Poly(3,4-ethylenedioxythiophene) poly(styrenesuflonate) (PEDOT:PSS) (such as CLEVIOS™ P VP Al 4083 and PH1000) was next used as a transparent conductor layer on top of the P3HT:PCBM layer. A first solution of PEDOT:PSS (Al 4083) was spincoated onto the P3HT:PCBM covered titanium foil at 1000 rpm for 1 minute and then at 2000 rpm for 1 minute. The dried film was annealed at 120° C. for 10 minutes.

A second solution of PEDOT:PSS (PH1000) with the addition of 5% dimethyl sulfoxide (DMSO) was sonicated for 30 minutes. The PH1000 solution was spun coated onto the PEDOT:PSS (Al 4083) layer at 1000 rpm for 1 minute and then at 2000 rpm for 1 minute. This was next annealed at 120° C. for 10 minutes.

The process for the PEDOT:PSS (PH1000) layer was repeated two more times to create a total of three layers of PH1000. A drop of PEDOT:PSS (PH1000) was next cast coat on the top as a thick layer. Silver paste was deposited on the thick layer of PEDOT:PSS (PH1000). Lastly, the sample was annealed at 120° C. for 10 minutes.

Once constructed as above, the unencapsulated solar cells were then characterized in ambient air using the Keithley 2400 source measure unit. The AM 1.5 solar simulator (100 mWcm-2) was used as the illumination source and the light intensity was calibrated using a standard silicon solar cell. The area of the devices was the illumination area minus the area of the thick layer of the PEDOT 1000.

FIG. 2 shows the J-V characteristics in dark and under illumination at 100 mA/cm² of the inverted solar cell on a titanium foil with proper surface treatment (etched in HF with a lower concentration). The FIG. 2 cell achieved a Voc of 0.46 V, a Jsc of 6.2 mA/cm², a fill factor (FF) of 35% and a calculated PCE of 0.98%.

As noted above, for comparison an inverted solar cell was also formed with the same (FIG. 1) layer structure on non-etched (“cleaned”) titanium foils and on etched titanium foils using HF of higher concentration (“over-etched”). The non-etched titanium foil-based solar cell presented an electrical short circuit and showed a non functional device as can be seen in the graph of FIG. 4. Thereafter, when the solar cell using the over-etched titanium foil (in HF of higher concentration) was tested, it displayed a small Voc of 0.33 V, a Jsc of 0.9 mA/cm², a fill factor (FF) of 27% and a PCE of 0.08% (FIG. 6).

The photovoltaic parameters of the three solar cells are summarized in the table of FIG. 7. From these data it can be concluded that the substrate treatment process has a significant impact on the device's performance. The titanium foil that was preferably etched with the HF having a concentration of 0.48 volume percent had superior performance compared to the foil over-etched with 4.8 volume percent HF and the cleaned foil (non-etched).

The surface morphology of the three types of substrates was evaluated by scanning electron microscope (SEM). As shown in FIGS. 3a, 3b, 5a, 5b, 8a and 8b, the non-etched titanium foil, the properly etched foil (etched in 0.48 volume percent HF) and the over-etched titanium foil (etched in 0.48 volume percent HF) present noticeable differences in morphology. The non-etched titanium foil shows (FIGS. 5a and 5b) obvious wear debris and scuffing which arose from the manufacturing process. Such debris and scuffing renders a high degree of roughness to the substrate and may be the source of the electrical short circuit and non-photovoltaic performance.

To improve the surface morphology of the titanium foil, as noted above, the titanium foil was etched in HF of different concentration (e.g., 4.8 volume percent and 0.48 volume percent) for 30 seconds. It was observed that debris and scuffing was removed completely from the titanium surfaces during etching using both concentrations of HF as shown in FIGS. 3a, 3b, 8a and 8b. These two etched titanium substrates presented a similar micropitted surface morphology, except that the properly etched (e.g., 0.48 volume percent HF) foil had less sharp edges and was much smoother than the over-etched (e.g., 4.8 volume percent HF) foil. The J-V performance and SEM results indicate that the smoother titanium surface structure leads to more efficient photovoltaic devices.

This detailed description in connection with the drawings is intended principally as a description of the presently preferred embodiments of the invention, and is not intended to represent the only form in which the present invention may be constructed or utilized. The description sets forth the designs, functions, means, and methods of implementing the invention in connection with the illustrated embodiments. It is to be understood, however, that the same or equivalent functions and features may be accomplished by different embodiments that are also intended to be encompassed within the spirit and scope of the invention and that various modifications may be adopted without departing from the invention or scope of the following claims.

1. A method of forming an organic photovoltaic cell, the method comprising:
(a) preparing a titanium electrode;
(b) depositing at least one layer on the titanium electrode sufficient to construct a photovoltaic cell.

2. The method in accordance with claim 1, wherein the step of preparing further comprises disposing at least one surface of the titanium electrode in an etching solution for a period of time sufficient to properly etch the surface.

3. The method in accordance with claim 1, wherein the step of preparing further comprises disposing at least one surface of the titanium electrode in an etching solution containing hydrofluoric acid for a period of time sufficient to properly etch the surface.

4. The method in accordance with claim 1, wherein the step of preparing further comprises disposing at least one surface of the titanium electrode in an etching solution containing about 0.48 volume percent hydrofluoric acid for a period of time sufficient to properly etch the surface.

5. The method in accordance with claim 1, wherein the step of preparing further comprises disposing at least one surface of the titanium electrode in an etching solution containing about 0.48 volume percent hydrofluoric acid for about 30 seconds.

6. The method in accordance with claim 1, wherein the step of depositing at least one layer further comprises mounting a layer of donor/acceptor polymer on said at least one surface of the titanium electrode.

7. The method in accordance with claim 6, wherein the step of depositing at least one layer further comprises depositing at least one substantially transparent, hole-conducting polymer layer on a surface of the donor/acceptor polymer layer.

8. The method in accordance with claim 7, wherein the step of depositing at least one layer further comprises mounting a buffer layer on said at least one substantially transparent, hole-conducting polymer layer.

9. The method in accordance with claim 8, wherein the step of depositing at least one layer further comprises mounting a conducting layer on said buffer layer.

10. The method in accordance with claim 9, wherein the step of depositing at least one layer further comprises mounting a blocking layer on said conducting layer.

11. A method of forming an organic photovoltaic cell, the method comprising:
(a) disposing a titanium foil in an etching solution containing about 0.48 volume percent hydrofluoric acid for about 30 seconds;
(b) depositing a layer of P3HT:PCBM on a first surface of the titanium foil;
(c) depositing a layer of PEDOT 4083 upon a surface of the P3HT:PCBM layer on an opposite side from the titanium foil;
(d) depositing at least a first layer of PEDOT 1000 on a surface of the PEDOT 4083 layer opposite the P3HT:PCBM layer; and
(e) depositing a silver paste on said at least a first layer of PEDOT 1000.

12. The method in accordance with claim 11, wherein the step of depositing at least a first layer of PEDOT 1000 on a surface of the PEDOT 4083 layer opposite the P3HT:PCBM layer further comprises depositing a second layer of PEDOT 1000 on the first layer of PEDOT 1000 and then depositing a third layer of PEDOT on the second layer of PEDOT 1000.

13. An organic photovoltaic cell comprising:
(a) a titanium electrode layer;
(b) at least one donor/acceptor polymer layer mounted to a surface of the titanium electrode layer;
(c) at least one hole-conducting polymer layer mounted to a surface of the donor/acceptor polymer layer; and
(d) an electrode mounted to a surface of the hole-conducting polymer layer.

14. The organic photovoltaic cell in accordance with claim 13, wherein the donor/acceptor layer comprises a P3HT:PCBM layer mounted on a first surface of the titanium electrode layer.

15. The organic photovoltaic cell in accordance with claim 14, wherein the hole-conducting polymer comprises at least one layer of PEDOT.

16. The organic photovoltaic cell in accordance with claim 15, wherein said at least one layer of PEDOT further comprises:
(a) a layer of PEDOT 4083 mounted upon a surface of the P3HT:PCBM layer on an opposite side from the titanium electrode layer;
(b) at least a first layer of PEDOT 1000 mounted on a surface of the PEDOT 4083 layer opposite the P3HT:PCBM layer; and
(d) a silver paste mounted on said at least a first layer of PEDOT 1000.

17. The organic photovoltaic cell in accordance with claim 16, wherein said at least a first layer of PEDOT 1000 mounted on a surface of the PEDOT 4083 layer opposite the P3HT:PCBM layer further comprises a second layer of PEDOT 1000 mounted on the first layer of PEDOT 1000 and a third layer of PEDOT mounted on the second layer of PEDOT 1000.
